(19) United States
(12) Patent Application Publication
(10) Pub. No.: US 2006/0022688 A1
(43) Pub. Date: Feb. 2, 2006

(54) Probe card

(75) Inventors: Tomohiro Giga, Kawasaki (JP); Kenji Togashi, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/016,943

(22) Filed: Dec. 21, 2004

(30) Foreign Application Priority Data
Jul. 29, 2004 (JP) 2004-221447

(51) Int. Cl. G01R 31/02

(52) U.S. Cl. 324/754

(57) ABSTRACT

A probe card is commonly used for a plurality of kinds of semiconductor chips. The probe card has a probe card substrate and a multi-layer structure interconnection substrate connected to the probe card substrate. A plurality of probe needles extend from the multi-layer structure interconnection substrate. At least one power supply plane is provided between the multi-layer structure interconnection substrate and extreme ends of the probe needles. The power supply plane is configured and arranged to be exchangeable with a different plane.

### CROSS-REFERENCE TO RELATED APPLICATIONS

The present application is based on Japanese priority application No. 2004-221447 filed Jul. 29, 2004, the entire contents of which are hereby incorporated herein by reference.

### BACKGROUND OF THE INVENTION

1. Field of the Invention

The present invention generally relates to probe cards and, more specifically, to a probe card having contact pins arranged at a small pitch.

2. Description of the Related Art

With the recent reduction in drive voltage and an increase in power consumption of semiconductor devices and electronic devices, contact pads of a semiconductor chip have become arranged all over the entire surface of the semiconductor chip and a pitch (interval) of the contact pads has become smaller.

A probe card used for testing such a semiconductor chip formed in a wafer generally comprises vertical type probe pins and a multi-layer interconnection substrate such as a multi-layer ceramic (MLC) substrate or a multi-layer organic (MLO) substrate. In such as probe card, a number of contact for power supply is increased so as to improve a power supply and prevent a voltage drop.

That is, in the recent semiconductor devices, since an interval of the contact pads is reduced to an order of 150 μm to 300 μm, if contact pins such as a probe needle or spring pin are arranged on a probe card substrate (performance board) for interfacing with a measuring machine (inspection machine), an ultra-fine fabrication technique is required for forming wirings in the performance board, which inevitably increases a cost of the performance board.

In order to solve the above-mentioned problem, Japanese Laid-Open Patent Application No. 11-96747 suggests a structure in which a multi-layer interconnection substrate having a finer structure than a performance board for interfacing with a measuring machine (inspection machine).

It should be noted that the multi-layer ceramic (MLC) substrate is a multi-layer wiring substrate using ceramics as a base material, and the multi-layer organic (MLO) substrate is a multi-layer wiring substrate using a resin as a base material. Generally, finer wirings can be formed in the MLC substrate than the MLO substrate.

A description will be given below, with reference to FIG. 1, of a conventional probe card using a multi-layer structure interconnection substrate. FIG. 1 is an illustrative cross-sectional view of a probe card using a multi-layer interconnection substrate.

In FIG. 1, the probe card 100 comprises: a performance board 101; a multi-layer structure interconnection substrate 102 such as an MLC substrate or an MLO substrate having a connection bumps 103 on one surface for connection with the performance board 101 and contact pads 104 on the other surface for connecting with probe pins 109; a probe pin fixing unit 105 having a plurality of positioning plates 106, 107 and 108; and the probe pins 109. A rear end of each of the probe pins 109 is provided with a cobra-shaped head 110 so as to prevent the probe pin from falling from the probe card 100 and to stabilize the contact with the contact pad 104.

In the probe card 100 having the abovementioned structure, a pitch of the contact pads 104 provided on one surface of the multi-layer structure interconnection substrate 102 is equal to a pitch of contact pads 112 for power supply and signals on a surface of a semiconductor chip formed in a semiconductor wafer 111 to be tested so that the contract pads 104 correspond to the contact pads 112 on one-to-one basis.

As mentioned above, since the contact pads 104 provided on one surface of the multi-layer structure inter interconnection substrate must be located in the same arrangement as the contact pads 112 provided on the semiconductor chip to be tested, the multi-layer structure interconnection substrate must be for exclusive use.

Accordingly, if positions of pads for power supply, which are a part of the pads of the semiconductor chip to be tested, are changed, an exclusive probe card must be newly fabricated so as to change the arrangement of the probe pins for power supply. Thus, there is a problem in that since the multi-layer structure interconnection substrate must be fabricated for each kind of semiconductor chips, a fabrication cost of the probe cards is extremely large.

Additionally, there is a problem in that it takes 10 to 12 weeks to fabricated a new probe card, which is longer than manufacturing time of semiconductor chips, and, thus, a new probe cannot be supplied at an appropriate timing before a wafer test.

In order to solve the above-mentioned problems, if a fabrication of a new probe card for a semiconductor chip is started in the middle of layout design work of pads for power supply so as to complete the new probe card before fabrication of the semiconductor chip, there is another problem in that a design change at a layout design stage cannot be reflected in the new probe card.

### SUMMARY OF THE INVENTION

It is a general object of the present invention to provide an improved and useful probe card in which the above-mentioned problems are eliminated.

A more specific object of the present invention is to provide a probe card which is commonly used for a plurality of kinds of semiconductor chips.

In order to achieve the above-mentioned objects, there is provided according to the present invention a probe card comprising: a probe card substrate; a multi-layer structure interconnection substrate connected to the probe card substrate; a plurality of probe needles extending from the multi-layer structure interconnection substrate; and at least one power supply plane provided between the multi-layer structure interconnection substrate and extreme ends of the probe needles, wherein the power supply plane is configured and arranged to be exchangeable.

Additionally, there is provided according to another aspect of the present invention a probe card comprising: a probe card substrate; a plurality of probe needles extending from the probe card substrate; and at least one power supply plane provided between the probe card substrate and extreme ends of the probe needles, wherein the power supply plane is configured and arranged to be exchangeable.

In the probe card according to the present invention, the power supply plane may have a plurality of through holes through which the probe needles extend, and at least a surface of the power supply pane facing an object to be tested is covered by a solid metal. Inner surfaces of the through holes of the power supply plane may be applied with an insulating treatment.

The probe card according to the present invention may further comprise a guide plane for positioning the probe needles is provided between the power supply plane and the extreme ends of the probe needles. The guide plane may have a monitor for positioning and a hole for positioning. The monitor for positioning may include at least one of send pad and a positioning mark for positing the through holes for the probe needles.

Additionally, there is provided according to another aspect of the present invention a method of testing a semiconductor chip using a probe card comprising a probe card substrate, a multi-layer structure interconnection substrate and a plurality of probe needles, the method comprising: placing at least one power supply plane between the multi-player structure interconnection substrate and extreme ends of the probe needles, the power supply plane being provided with contact pads being located in an arrangement corresponding to an arrangement of power supply pads of the semiconductor chip;
contacting the probe needles with electrode pads of the semiconductor chip; and performing a test on the semiconductor chip.

Further, there is provided according to another aspect of the present invention a method of testing a semiconductor chip using a probe card comprising a probe card substrate and a plurality of probe needles, the method comprising: placing at least one power supply plane between the probe card and extreme ends of the probe needles, the power supply plane being provided with contact pads being located in an arrangement corresponding to an arrangement of power supply pads of the semiconductor chip; contacting the probe needles with electrode pads of the semiconductor chip; and performing a test on the semiconductor chip.

Other objects, features and advantages of the present invention will become more apparent from the following detailed description when read in conjunction with the accompanying drawings.

### BRIEF DESCRIPTION OF THE DRAWINGS

FIG. 1 is an illustrative cross-sectional view of a probe card using a multi-layer interconnection substrate;

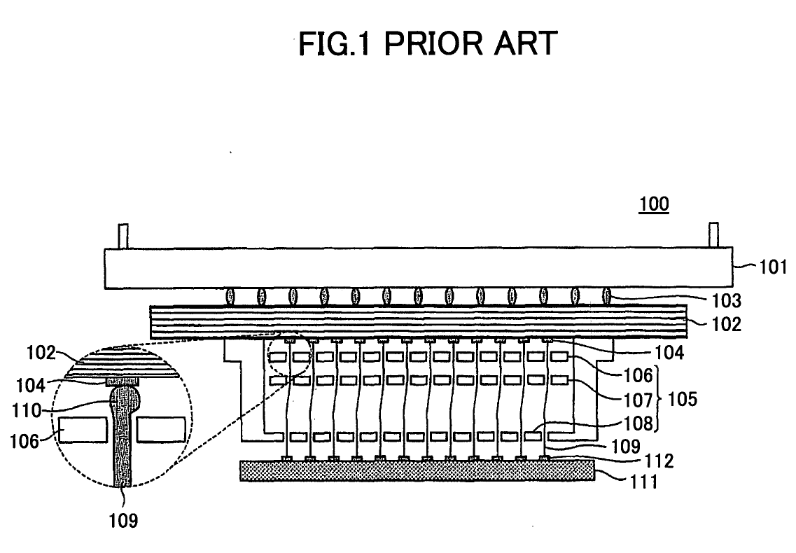

FIG. 2 is an illustrative side view of a probe card according to the present invention.

FIGS. 3A, 3B and 3C are plan views of a power supply plane, a GND plane and a positioning plane, respectively, that constitute a probe card;

FIGS. 4A, 4B and 4C are plan views of the planes shown in FIGS. 3A, 3B and 3C, respectively, before performing assembly work;

FIG. 5 is an illustrative cross-sectional view of a probe card according to a first embodiment of the present invention;

FIG. 6 is an illustrative cross-sectional view of the probe-card according to the first embodiment of the present invention after design change;

FIG. 7 is an illustrative cross-sectional view of a probe card according to a second embodiment of the present invention; and

FIG. 8 is an illustrative cross-sectional view of a probe card according to a third embodiment of the present invention.

### DETAILED DESCRIPTION OF THE PREFERRED EMBODIMENTS

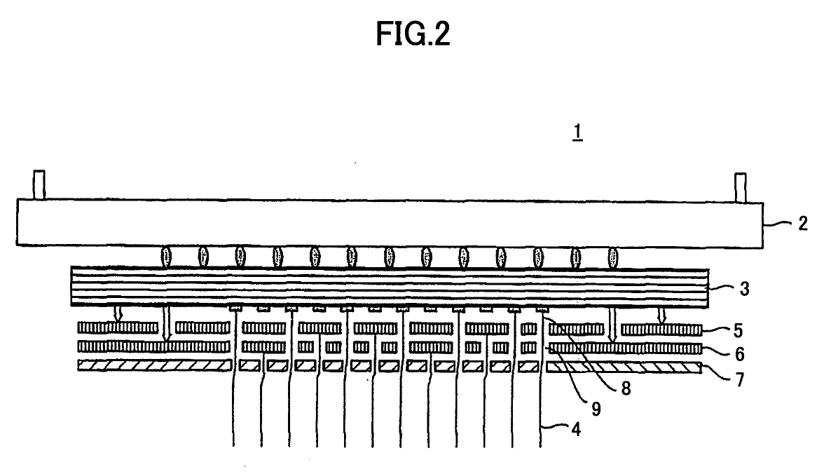

A description will be given first, with reference to FIG. 2, of a principle of the present invention. FIG. 2 is an illustrative side view of a probe card according to the present invention.

The probe card 1 according to the present invention comprises: a probe card substrate 2, a multi-layer structure interconnection substrate 3 and a plurality of probe needles 4. The probe card 1 is also provided with at least one power supply plane (two power supply planes 5 and 6 in the example of FIG. 2), which is exchangeable, between the multi-layer structure interconnection substrate 3 and extreme ends of the probe needles 4.

By providing the power supply planes 5 and 6, if an arrangement of power supply pads on a semiconductor chip to be tested is changed, only a design of the power supply planes 5 and 6 is changed. That is, there is no need to develop a new and exclusive probe card, and the change in the arrangement of power supply pads can be reflected in the existing probe card 1 without developing a new probe card.

In such as case, new power supply planes 5 and 6 can be fabricated within 3 to 4 weeks, which is about one-third (⅓) of a time period for fabricating a new probe card. Thus, a design change at a pad layout design stage can be reflected in the probe card 1. Additionally, a cost relating to the design change is reduced since only new power supply planes to be replaced with the power supply planes 5 and 6 are to be fabricated.

It should be noted that the power supply planes 5 and 6 may include a grounding plane in this case.

The above-mentioned structure is applicable to a probe card 1, which does not use the multi-layer structure interconnection substrate 3. In such a case, at least one of the power supply planes 5 and 6, which are exchangeable, may be provided between the probe card substrate 2 and the extreme ends of the probe needles 4 without providing the multi-layer structure interconnection substrate 3.

It should be noted that when using the multi-layer structure interconnection substrate 3, it is considered that the multi-layer structure interconnection substrate 3 is a part of the probe card substrate 2. Thus, using or not using the multi-layer structure interconnection substrate 3 is irrelevant to the present invention.

When the multi-layer structure interconnection substrate 3 is not use, it is preferable that the power supply planes 5 and 6 have through holes 8 and 9 for passing the probe needles 4 therethrough and at least a surface of the power supply planes 5 and 6 facing an object to be tested is covered by a solid metal, which may be formed by a plating method or a vapor deposition method.

In such a case, it is preferable that inner surfaces of the through holes 8 and 9 are insulating surfaces so as to prevent short-circuiting by preventing the signal probe needles 4 extending through the through holes 8 and 9 from being brought in contact with the power supply planes 5 and 6 or the power supply probe needles 4, which are to be contacted with on of the power supply planes 5 an 6, are prevented from being brought into contact with the other of the power supply planes 5 and 6.

Additionally, it is preferable to provide a guide plane 7 used for positioning and alignment of the probe needles between the power supply planes 5 and 6 and the extreme ends of the probe needles 4 so as to prevent short-circuiting by preventing the signal probe needles 4 extending through the through holes 8 and 9 from being brought in contact with the power supply planes 5 and 6 or the power supply probe needles 4, which are to be contacted with on of the power supply planes 5 an 6, are prevented from being brought into contact with the other of the power supply planes 5 and 6.

Further, it is preferable to provide positioning monitors including positioning marks for the sense pads or the though holes 8 and 9 for the probe needles 4 and the positioning holes 8 an 9 to the power supply planes 5 and 6 and the guide plane 7 so as to facilitate positioning of the exchangeable power supply planes 5 and 6.

According to the present invention, even if a design change is made in the layout of the signal pads, the power supply pads and grounding (GND) pads, there is no need to newly fabricate a multi-layer structure interconnection substrate and a large reduction in delivery and a large cost reduction by the common use of the probe card can be achieved. Additionally, electric properties of the probe card is also improved.

According to the present invention, the exchangeable power supply planes are provided in addition to the guide plane for positioning the probe pins (needles) so as to position the probe pins relative to the multi-layer structure interconnection substrate. The positions of the through holes provided to the power supply planes are changed so that a change in the layout of the signal pads, power supply pads and GND pads in a product chip is reflected in the probe card.

Additionally, if a reduction in a pad pitch of contact pads in the performance board progresses in the future, the exchangeable power supply plane is provided in addition to the guide plane for positioning the probe pins so as to position the probe pins directly to the performance board without using a multi-layer structure interconnection substrate.

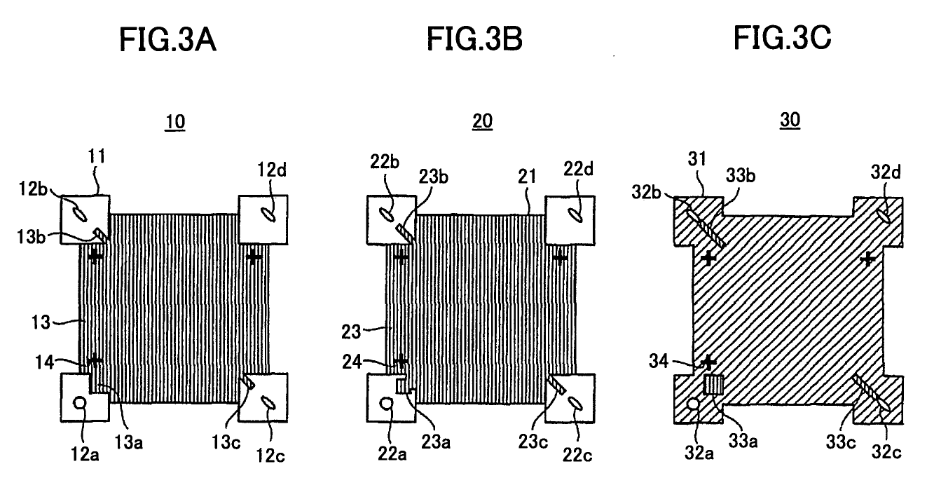

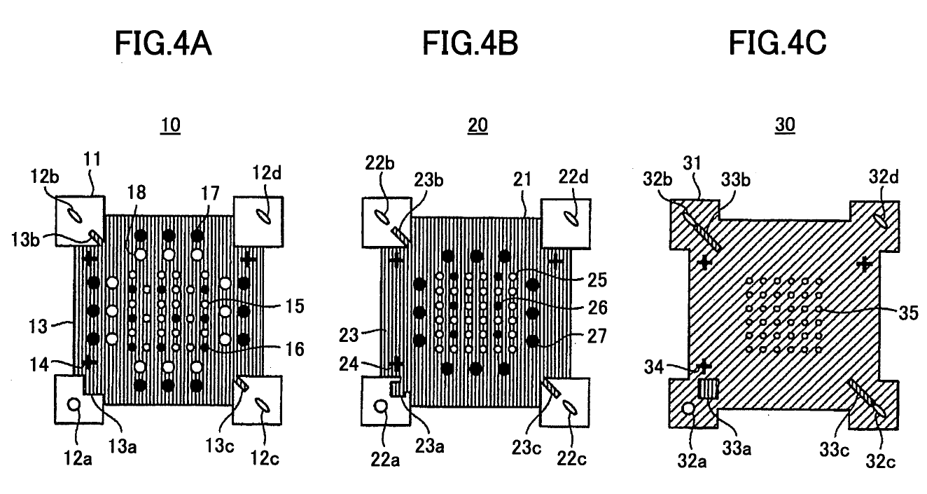

A description will now be given, with reference to FIG. 3A through FIG. 6, of a probe card according to a first embodiment of the present invention. FIGS. 3A, 3B and 3C are plan views of a power supply plane, a GND plane and a positioning plane, respectively, that constitute the probe card. FIGS. 4A, 4B and 4C are plan views of the planes shown in FIGS. 3A, 3B and 3C, respectively, before performing assembly work. It should be noted that each plane shown in FIGS. 3A through 4C has a outer configuration of 50 mm square, and an enlarged portion is provided on each corner.

Referring to FIG. 3A, the power supply plane 10 is formed of a solid metal layer 13 that is formed by applying Au-plating onto a surface of an aluminum (Al) substrate 11. A positioning base sense pad 13a is provided at one corner of the solid metal layer 13. Additionally, positioning sense pads 13b and 13c each of which is smaller than the positioning base sense pad 13a are provided to corners adjacent to the corner at which the positioning base sense pad 13a is provided.

The positioning base sense pad 13a and the positioning sense pads 13b and 13c are for checking positioning by checking electric conduction between the pads. In the present embodiment, each of the positioning sense pads 13b and 13c is configured to be an elongated rectangular shape extending in a diagonal line so as to facilitate the positioning of the plane by rotating the Al substrate 11 about the positioning base sense pad 13a as a center of rotation circle.

Additionally, a positioning hole is provided to the enlarged portion of each of the four corners of the Al substrate 11 constituting the power supply plane 10. For example, a circular positioning base hole 12a is provided to the enlarged portion corresponding to the positioning base sense pad 13a, while other positioning holes 12b, 12c and 12d are formed in an oblong shape having a longer axis extending in the longitudinal direction of the positioning sense pads 13b and 13c.

Further, positioning marks 14 are provided to the solid metal layer 13 so as to use in positioning of through holes for probe pins mentioned later. In the present embodiment, cross marks are formed as the positioning marks 14 at three positions.

Referring to FIG. 3B, the GND plane 20 is formed of a solid metal layer 23 that is formed by applying Au-plating onto a surface of an aluminum (Al) substrate 21. Similar to the power supply plane 10, a positioning base sense pad 23a is provided at one corner of the solid metal layer 23. Additionally, positioning sense pads 23b and 23c each of which is smaller than the positioning base sense pad 23a are provided to corners adjacent to the corner at which the positioning base sense pad 23a is provided. It should be noted that each of the positioning sense pads 23b and 23c is configured to be an elongated rectangular shape extending in a diagonal line.

Additionally, a positioning hole is provided to the enlarged portion of each of the four corners of the Al substrate 21 constituting the GND plane 20. A circular positioning base hole 22a is provided to the enlarged portion corresponding to the positioning base sense pad 23a, while other positioning holes 22b, 22c and 22d are formed in an oblong shape having a longer axis extending in the longitudinal direction of the positioning sense pads 23b and 23c.

Further, positioning marks 24 are provided to the solid metal layer 23 so as to use in positioning. In the present embodiment, cross marks are formed as the positioning marks 24 at three positions.

Referring to FIG. 3C, the positioning plane 30 is formed of a glass substrate 31. A positioning base sense pad 33a is formed at one of the four corners of the glass substrate 31 by applying Au-plating. Additionally, positioning sense pads 33b and 33c each of which is smaller than the positioning base sense pad 33a are provided to corners adjacent to the corner at which the positioning base sense pad 33a is provided.

It should be noted that each of the positioning sense pads 33b and 33c is configured to be an elongated rectangular shape extending in a diagonal line so as to facilitate the positioning relative to other planes by rotating the glass substrate 31 about the positioning base sense pad 33a as a center of rotation circle.

Additionally, a positioning hole is provided to the enlarged portion of each of the four corners of the glass substrate 31 constituting the positioning plane 30. A circular positioning base hole 32a is provided to the enlarged portion corresponding to the positioning base sense pad 33a, while other positioning holes 32b, 32c and 32d are formed in an oblong shape having a longer axis extending in the longitudinal direction of the positioning sense pads 33b and 33c.

Further, positioning marks 34 are provided to the glass substrate 31 so as to use in positioning. In the present embodiment, cross marks are formed as the positioning marks 34 at three positions.

Referring to FIG. 4C, through holes 35 are formed in the center portion of the positioning plane 30 for positioning the probe pins so that the probe pins extend through the respective through holes 35. In the present embodiment, thirty six through holes 35 are shown in FIG. 4C.

Referring to FIG. 4B, through holes 25 are formed in the GND plane 20 at positions corresponding to the through holes 35 provided in the positioning plane 30 by using the positioning marks 24 as a reference. Additionally, the through holes 25 are not provided at positions where the probe pins for GND are received, and, instead, contact pads 26 are formed at those positions. In FIG. 4B, six contact pads 26 are indicated.

An insulating treatment is applied to the inner surfaces of the through holes 25 so as to prevent the signal probe pins extending through the through holes 25 from short-circuiting with the GND plane 20. Additionally, contact pads 27 are formed in a peripheral portion of the other surface of the Al substrate 21.

Referring to FIG. 4A, through holes 15 are formed in the GND plane 10 at positions corresponding to the through holes 25 provided in the GND plane 20 by using the positioning marks 14 as a reference. However, the through holes 25 are not provided at positions where the probe pins for power supply are received, and, instead, contact pads 16 are formed at those positions. In FIG. 4A, signal contact pads 16 are indicated.

An insulating treatment is applied to the inner surfaces of the through holes 15 so as to prevent the signal probe pins extending through the through holes 15 from short-circuiting with the power supply plane 10.

Opening parts 18 are provided in a peripheral portion of the other surface of the Al substrate 11 at positions corresponding to the contact pads 27 provided in the GND plane 20. Additionally, contact pads 17, which correspond to connection probe pins for power supply provided to an MLC substrate mentioned later, are formed outside the opening parts 18

An insulating treatment is also applied to inner surfaces of the opening parts 18 so as to prevent the GND probe pins extending through the opening parts 18 from short-circuiting with the power supply plane 10.

It should be noted that through holes 15 and 25 are formed larger than the through holes 35 provided in the positioning plane 30.

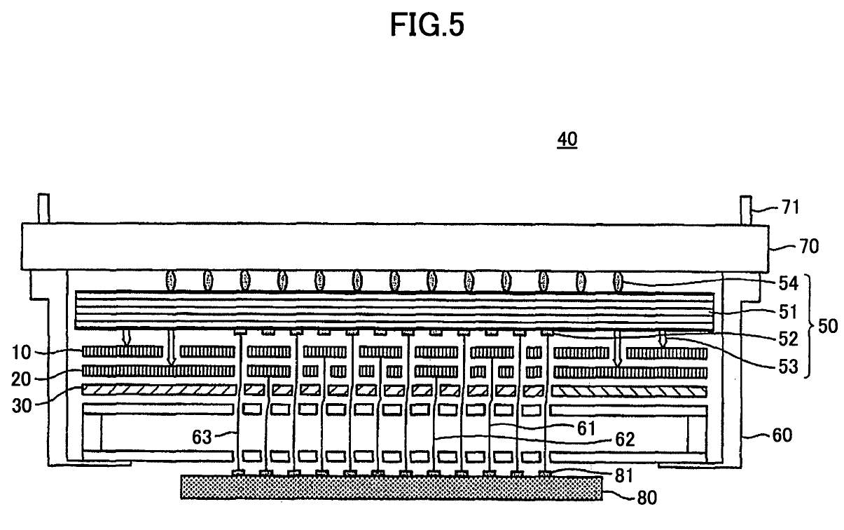

FIG. 5 is an illustrative cross-sectional view of the probe card according to the first embodiment of the present invention. In FIG. 5, contact pads 52 are provided on one surface of a base part 51, the contact pads 52 being formed by using a positioning jig. Contact pins 53 for power supply plane 10 and the GND plane 20 are provided in a peripheral part of the contact pads 52. Connection bumps 54 for connecting with a performance board 70 are provided on the other surface of the base part 51. The base part 51, the contact pads 52, the contact pins 53 and the connection bumps 54 together constitute an MLC substrate 50. The power supply plane 10, the GND plane 20 and the positioning plane 30 are stacked sequentially on the MLC substrate 50 while positioning, and are fixed to the MLC substrate 50 by screws.

Then, the signal probe pins 63, the GND probe pins 62 and the power supply probe pins 61 are inserted into the through holes and implanted to the MLC substrate 50 using a fixing unit 60. At this time, ends of the probe pins 61, 62 and 63 contacting the contact pads 16, 26 and 52, respectively, are formed as cobra-like head so as to prevent the probe pins from falling off from the probe card 40 and to acquire stability of contact.

The probe pins 61, 62 and 63 include a plurality of kinds having upper portions of different lengths so as to equalize lengths of portions protruding from the positioning plane 30. For example, the signal probe pins 63 may be one kind, but the GND probe pins require a number of kinds corresponding to a number of GND planes 20, and also the power supply probe pins 61 require a number of kinds corresponding to the power supply planes 10.

As mentioned above, the basic structure of the probe card 40 is completed by stacking the MLC substrate and the planes and connecting the MLC substrate 50, to which the probe pins 61, 62 and 63 are implanted, to the performance board 70 using the connection bumps 54. It should be noted that connecters 71 for connecting a tester are provided to the performance board 70.

Using the thus-constructed probe card 40, the probe pins 61, 62 and 63 are brought into contact with contact pads 81 provided in a semiconductor integrated circuit device 80 so as to acquire signals at contact pads 71 from the tester connecting connecters 71 through the signal probe pins. In such as case, the probe pins 61, 62 and 63 can be arranged as indicated in the figure, for example, from the left side, “signal-GND-signal-power supply-signal-power supply-signal-GND-signal-power supply-signal-signal”.

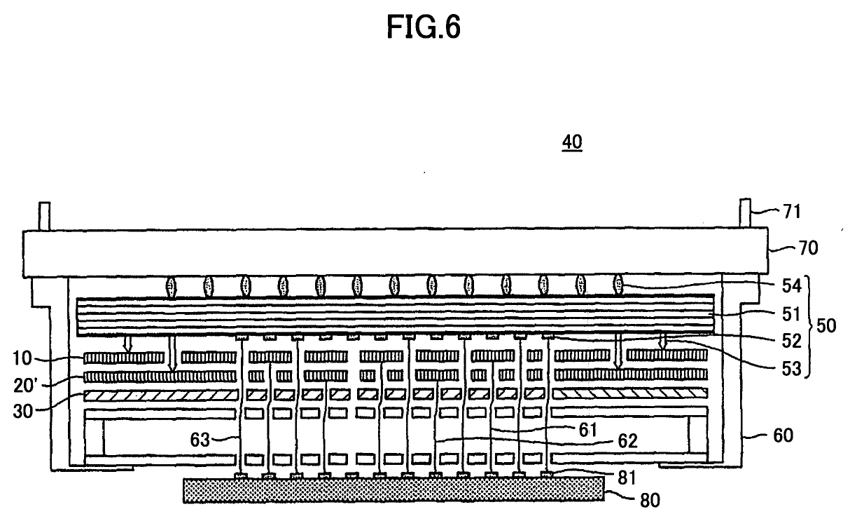

FIG. 6 is an illustrative cross-sectional view of the probe-card according to the first embodiment of the present invention after design change. FIG. 6 shows a case where the arrangement of the five pads on the left side among the contact pads 81 of the semiconductor integrated circuit device 80 is changed from “signal-GND-signal-power supply-signal” to “signal-power supply-signal-GND-not used”. In the present embodiment, the design change of the pad layout is reflected by changing positions of the through holes 25 provided to a GND plane 20A.

As mentioned above, in the first embodiment of the present invention, a change in the arrangement of the contact pads 81 caused by a design change in internal circuits of the semiconductor integrated circuit device 80 can be reflected in the probe card 40 by merely changing the GND plane 20. Since there is no need to change the design of the MLC substrate 50, a design change in the semiconductor integrated circuit device can be quickly reflected in the probe card 40.

For example, it takes 10 to 12 weeks to newly fabricate the MLC substrate 50, which is longer than production time of a semiconductor chip. Accordingly, there may be a case where the production of the probe card cannot complete in time. However, according to the probe card according to the present embodiment, it takes 3 to 4 weeks to fabricate a new power supply plane 10 or GND plane 20, it takes only one-third (⅓) of a time period for producing an exclusive probe card, which enables to reflect a design change at a layout design stage in the probe card and also reduce a manufacturing cost of the probe card.

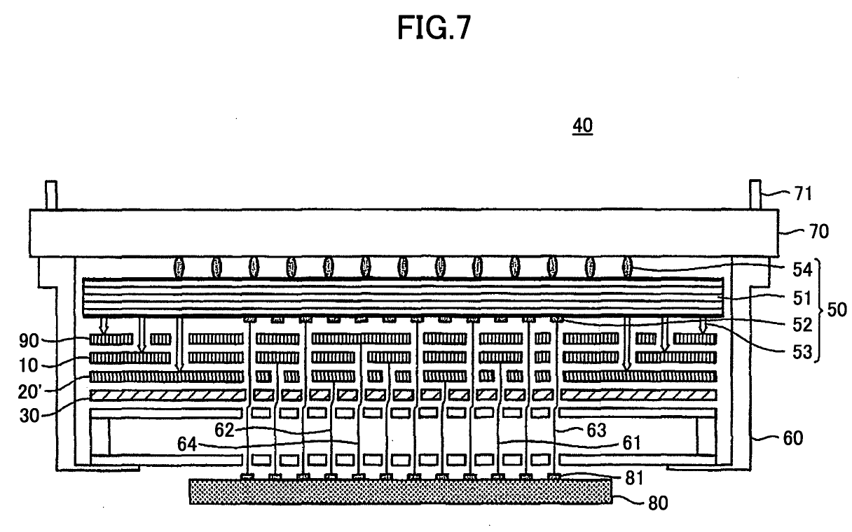

A description will now be given, with reference to FIG. 7, of a probe card according to a second embodiment of the present invention. FIG. 7 is an illustrative cross-sectional view of the probe card according to the second embodiment of the present invention. FIG. 7 shows a case in which the arrangement of the probe pins 61, 62 and 63 shown in FIG. 5 is changed from “signal-GND-signal-power supply-signal” to “signal-power supply 1-signal-GND-pwere supply 2”.

In the second embodiment, two kinds of power supply planes are used. A second power supply plane 90 is used to constitute the probe card so as to reflect a change in the arrangement of the contact pads, that is, a change in the arrangement of the probe pins 61, 62 and 63. Additionally, a GND plane 20A provided with the through holes 25 in a different arrangement is used in the probe card.

It should be noted that, in the present embodiment, in order to increase a number of power supply planes, four kinds of probe pins are prepared and lengths of the probe pins 63 and 64 must be increased.

As mentioned above, when two kinds of power supply are used, the probe card can be changed by merely preparing two power supply planes and changing the arrangement of the through holes provided in the GND plane. Thus, a design change at a layout design stage can be reflected in the probe card, and a cost reduction can be achieved.

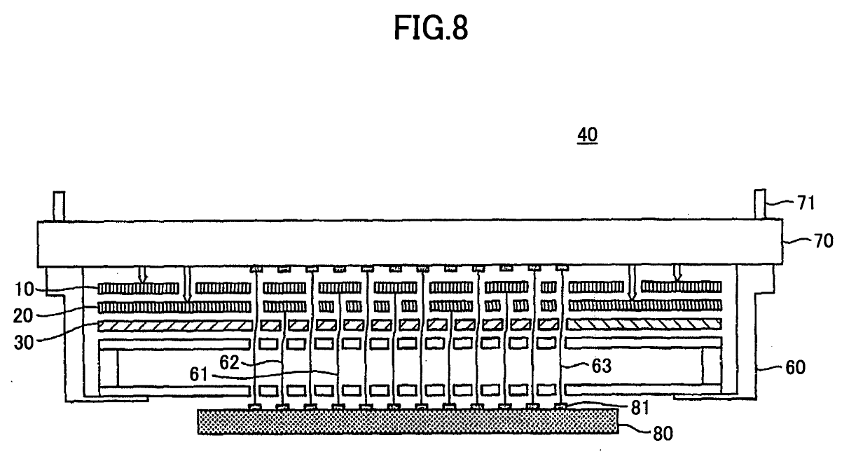

A description will now be given, with reference to FIG. 8, of a probe card according to a third embodiment of the present invention. FIG. 8 is an illustrative cross-sectional view of the probe card according to the third embodiment of the present invention. In the present embodiment, the MLC substrate is not used but each plane is stacked directly on the performance board 70. Other structures are the same as that of the probe card according to the above-mentioned first embodiment.

In the present embodiment, a structure of the probe card is simplified since an MLC substrate, which is an interconnection substrate, is not used. However, in such as case, it is required to arrange the contact pads on the performance board at a small (fine) pitch.

The present invention is not limited to the above-mentioned embodiments, and variations and modifications may be made without departing from the scope of the present invention. For example, sizes, configurations, a number of holes, a number of pins are not limited to the specifically disclosed values or shapes, and the material or the manufacturing may be changed, if necessary.

For example, although the Al substrate is used as a base of the power supply plane or the GND plane in the above-mentioned embodiments, a metal substrate such as a copper (Cu) substrate or the like may be used. Additionally, a base may be formed by applying Au plating or Cu plating on a surface of an insulating substrate such as a glass substrate, a polyimide substrate or a printed board.

Additionally, although a glass substrate is used as a base of the positioning plane in the above-mentioned embodiments, other insulating substrate such as a polyimide substrate or the like may be used.

Further, although the solid metal layer is formed by a plating method in the above-mentioned embodiments, the solid metal may be formed by other film deposition methods such as a vacuum vapor deposition method or the like.

Additionally, although the cross marks are used as the positioning marks 14, 24 and 34 in the above-mentioned embodiments, the positioning mark is not limited to the cross mark, and other shapes such as a square, a triangle, a diamond or the like may be used for the shape of the positioning mark. A number of positions at which the positioning marks are provided is not limited to three, and four positioning marks may be provided at different four positions.

Additionally, although the sense pads including the base sense pads are provided at three positions in the above-mentioned embodiments, the sense pads may be provided at more than for positions.

Additionally, the power supply plane, the GND plane and the positioning plane are fixed by screws after being stacked one on another in the above-mentioned embodiments, the fixing means is not limited to screws and the planes may be fixed using an insulating adhesive.

Additionally, although the probe pins are assumed to be inserted individually into the respective through holes one by one in the above-mentioned embodiments, the probe pins may be bundled in a matrix arrangement so as to be inserted into the through holes and implanted to the substrate at once. Probe pins that becomes unnecessary sue to a design change may be removed or cut off or fused after the implantation.

Additionally, although the MLC substrate, in which fine wirings can be formed, is used as an interconnection substrate in the above-mentioned embodiments, the interconnection board is not limited to the MLC substrate and other multi-layer structure interconnection substrate such as a MOL substrate using a resin instead of ceramics may be used.

Additionally, although a design change is not made to the power supply plane 10 in the above-mentioned embodiments, a design change may be made to the power supply plane 10 instead of the GND plane 20 when changing the arrangement of the power supply probe pins and the signal probe pins. Of course, a design change may be made to both the power supply plane 10 and the GND plane 20 due to a change in the arrangement of the probe pins.

Additionally, although one positioning plane 30 is used in the above-mentioned embodiments for the sake of simplification of the drawings. An additional positioning plane may be provided between the power supply plane 10 and the GND plane 20. According to such a structure, the probe pins 61 to 64 can be positively guided, and the power supply plane 10 and the GND plane 20 can be prevented from being short-circuited with each other.

Additionally, although the design change in the probe card according to the first embodiment was not specifically explained, the planes may be newly combined or only the GND plane may be replaced with a new plane by unfastening screws in the structure shown in FIG. 5.

The present invention is not limited to the specifically disclosed embodiments, and variation and modification may be made without departing from the scope of the present invention.

What is claimed is:

1. A probe card comprising:
a probe card substrate;
a multi-layer structure interconnection substrate connected to said probe card substrate;
a plurality of probe needles extending from said multi-layer structure interconnection substrate; and
at least one power supply plane provided between said multi-layer structure interconnection substrate and extreme ends of said probe needles,
wherein said power supply plane is configured and arranged to be exchangeable.

2. The probe card as claimed in claim 1, wherein said power supply plane has a plurality of through holes through which said probe needles extend, and at least a surface of said power supply pane facing an object to be tested is covered by a solid metal.

3. The probe card as claimed in claim 2, wherein inner surfaces of said through holes of said power supply plane are applied with an insulating treatment.

4. The probe card as claimed in claim 1, further comprising a guide plane for positioning said probe needles is provided between said power supply plane and said extreme ends of said probe needles.

5. The probe card as claimed in claim 4, wherein said guide plane has a monitor for positioning and a hole for positioning.

6. The probe card as claimed in claim 5, wherein said monitor for positioning includes at least one of send pad and a positioning mark for positing said through holes for said probe needles.

7. A probe card comprising:
a probe card substrate;
a plurality of probe needles extending from said probe card substrate; and
at least one power supply plane provided between said probe card substrate and extreme ends of said probe needles,
wherein said power supply plane is configured and arranged to be exchangeable.

8. The probe card as claimed in claim 7, wherein said power supply plane ha a plurality of through holes through which said probe needles extend, and at least a surface of said power supply pane facing an object to be tested is covered by a solid metal.

9. The probe card as claimed in claim 8, wherein inner surfaces of said through holes of said power supply plane are applied with an insulating treatment.

10. The probe card as claimed in claim 7, further comprising a guide plane for positioning said probe needles is provided between said power supply plane and said extreme ends of said probe needles.

11. The probe card as claimed in claim 10, wherein said guide plane has a monitor for positioning and a hole for positioning.

12. The probe card as claimed in claim 11, wherein said monitor for positioning includes at least one of send pad and a positioning mark for positing said through holes for said probe needles.

13. A method of testing a semiconductor chip using a probe card comprising a probe card substrate, a multi-layer structure interconnection substrate and a plurality of probe needles, the method comprising:
placing at least one power supply plane between said multi-player structure interconnection substrate and extreme ends of said probe needles, said power supply plane being provided with contact pads being located in an arrangement corresponding to an arrangement of power supply pads of said semiconductor chip;
contacting said probe needles with electrode pads of said semiconductor chip; and
performing a test on said semiconductor chip.

14. A method of testing a semiconductor chip using a probe card comprising a probe card substrate and a plurality of probe needles, the method comprising:
placing at least one power supply plane between said probe card and extreme ends of said probe needles, said power supply plane being provided with contact pads being located in an arrangement corresponding to an arrangement of power supply pads of said semiconductor chip;
contacting said probe needles with electrode pads of said semiconductor chip; and
performing a test on said semiconductor chip.
